(19) United States
(12) Patent Application Publication
(10) Pub. No.: US 2025/0022764 A1
(43) Pub. Date: Jan. 16, 2025

(54) SEMICONDUCTOR PACKAGE COMPRISING ADHESION ENHANCER LAYER AND METHOD OF FABRICATING THE SAME

(71) Applicant: Samsung Electronics Co., Ltd., Suwon-si (KR)

(72) Inventors: Minjung KIM, Suwon-si (KR); Solji SONG, Suwon-si (KR); Jiseok YEO, Suwon-si (KR); Hyojun YOON, Suwon-si (KR); Dongjin LEE, Suwon-si (KR); Yoonseok CHOI, Suwon-si (KR)

(73) Assignee: Samsung Electronics Co., Ltd., Suwon-si (KR)

(21) Appl. No.: 18/412,770

(22) Filed: Jan. 15, 2024

(30) Foreign Application Priority Data
Jul. 13, 2023 (KR) 10-2023-0091131

(51) Int. Cl. H01L 23/31; H01L 23/00; H01L 25/065

(52) U.S. Cl. CPC H01L 23/3142; H01L 23/3128; H01L 24/32; H01L 24/48; H01L 24/73; H01L 25/0652; H01L 2224/32145; H01L 2224/32225; H01L 2224/48145; H01L 2224/48227; H01L 2224/73265; H01L 2225/06562

(57) ABSTRACT

A semiconductor package is provided. The semiconductor package includes a package substrate including bonding pads on a upper surface thereof and external connectors on a lower surface thereof, a first chip structure connected to the package substrate with a bonding wire and disposed on the package substrate, a second chip structure disposed on the package substrate and disposed next to the first chip structure, and a mold layer covering the package substrate, the first chip structure, and the second chip structure, wherein the first chip structure includes a plurality of semiconductor dies that are sequentially stacked, the second chip structure includes a second semiconductor substrate, an oxide layer on the second semiconductor substrate, and an adhesion enhancer layer disposed on the oxide layer and in contact with the mold layer, heights of the first chip structure and the second chip structure are the same.

### CROSS-REFERENCE TO RELATED APPLICATIONS

This U.S. non-provisional patent application claims priority under 35 U.S.C. § 119 to Korean Patent Application No. 10-2023-0091131, filed on Jul. 13, 2023, in the Korean Intellectual Property Office, the entire contents of which are hereby incorporated by reference.

### BACKGROUND OF THE INVENTION

The present disclosure relates to a semiconductor package and a method of fabricating the same, and more specifically, to a semiconductor package having an adhesion enhancer layer and a method of fabricating the same.

A semiconductor package is provided to implement an integrated circuit chip to qualify for use in electronic products. Typically, a semiconductor package is configured such that a semiconductor chip is mounted on a printed circuit board (PCB) and bonding wires or bumps are used to electrically connect the semiconductor chip to the printed circuit board. Various research for improving reliability and durability of semiconductor packages have been conducted with the development of an electronic industry.

### SUMMARY

An object of the present disclosure is to provide a semiconductor package with improved adhesion of the semiconductor chip to improve durability and reliability.

An object of the present disclosure is to provide a method of fabricating a semiconductor package with improved yield.

A semiconductor package according to some embodiments of the present disclosure includes a package substrate including external connectors on a lower surface of the package substrate; a first chip structure on the package substrate and connected to the package substrate with a bonding wire; a second chip structure on the package substrate and next to the first chip structure; a mold layer covering the package substrate, the first chip structure, and the second chip structure; and an adhesion enhancer layer on an upper surface of the second chip structure, such that the adhesion enhancer layer is in contact with the mold layer.

A semiconductor package according to some embodiments of the present disclosure includes a package substrate including bonding pads on an upper surface of the package substate and external connectors on a lower surface of the package substrate; a first chip structure on the package substrate and connected to the package substrate with a bonding wire; a second chip structure on the package substrate and next to the first chip structure; and a mold layer covering the package substrate, the first chip structure, and the second chip structure, wherein the first chip structure includes a plurality of semiconductor dies that are sequentially stacked, the second chip structure includes a second semiconductor substrate, an oxide layer on the second semiconductor substrate, and an adhesion enhancer layer on the oxide layer and in contact with the mold layer, heights of the first chip structure and the second chip structure are the same, and the adhesion enhancer layer has a thickness within a range of 1 μm to 100 μm.

A semiconductor package according to some embodiments of the present disclosure includes a package substrate including bonding pads on an upper surface of the package substrate and external connectors on a lower surface of the package substrate; a first chip structure on the package substrate and connected to the package substrate with a bonding wire; a second chip structure disposed on the package substrate and next to the first chip structure; internal connectors between the package substrate and the second chip structure; and a mold layer covering the substrate, the first chip structure, and the second chip structure, wherein heights of the first chip structure and the second chip structure are the same, the first chip structure includes a plurality of first semiconductor dies that are sequentially stacked, wherein the second chip structure includes a second semiconductor die, an adhesive layer on the second semiconductor die, a reinforcing material on the adhesive layer, an oxide layer on the reinforcing material, and an adhesion enhancer layer on the oxide layer, and the adhesion enhancer layer includes an acrylic polymer

A method of fabricating a semiconductor package according to some embodiments of the present disclosure includes preparing a wafer surface protection tape, the wafer surface protection tape including a base film, a sacrificial adhesive layer, an adhesion enhancer layer, and a release film sequentially stacked; exposing the adhesion enhancer layer by removing the release film; attaching a semiconductor wafer to the wafer surface protection tape such that a front surface of the semiconductor wafer is in contact with an upper surface of the adhesion enhancer layer; grinding a back surface of the semiconductor wafer; forming an adhesive layer on the ground back surface of the semiconductor wafer; irradiating ultraviolet rays to remove the base film and the sacrificial adhesive layer; dicing the semiconductor wafer to form chip structures; attaching one of the chip structures to a package substrate; and forming a mold layer covering the package substrate and the chip structure.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1A is a cross-sectional view of a semiconductor package according to embodiments of the inventive concepts.

FIG. 1B is an enlarged view of portion ‘P1’ of FIG. 1A.

FIGS. 1C to 1F are enlarged views of portion ‘P2’ of FIG. 1A according to embodiments of the inventive concepts.

FIG. 2 is a cross-sectional view of a wafer surface protection tape according to embodiments of the inventive concepts.

FIGS. 3A to 3E are cross-sectional views sequentially showing the process of fabricating a first semiconductor die of FIG. 1A according to embodiments of the inventive concepts.

FIG. 4 is an enlarged view of portion ‘P3’ of FIG. 3B.

FIGS. 5A to 5I are cross-sectional views sequentially showing the process of fabricating a semiconductor package of FIG. 1A according to embodiments of the inventive concepts.

FIG. 6 is a cross-sectional view of a semiconductor package according to embodiments of the inventive concepts.

FIG. 7 is a cross-sectional view of a semiconductor package according to embodiments of the inventive concepts.

### DETAILED DESCRIPTION

Hereinafter, to explain the inventive concepts in more detail, embodiments according to the inventive concepts will be described in more detail with reference to the accompanying drawings. In the drawings, like reference numerals denote like elements and the sizes of the elements may be exaggerated for clarity and convenience of description. Also, the embodiments described below are only examples and various modifications may be made from such embodiments.

When the terms “about” or “substantially” are used in this specification in connection with a numerical value, it is intended that the associated numerical value includes a manufacturing tolerance (e.g., ±10%) around the stated numerical value. Further, regardless of whether numerical values are modified as “about” or “substantially,” it will be understood that these values should be construed as including a manufacturing or operational tolerance (e.g., ±10%) around the stated numerical values. When referring to “C to D”, this means C inclusive to D inclusive unless otherwise specified.

Additionally, spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, device may be otherwise oriented, for example, rotated 90 degrees or at other orientations, and the spatially relative descriptors used herein should be interpreted accordingly.

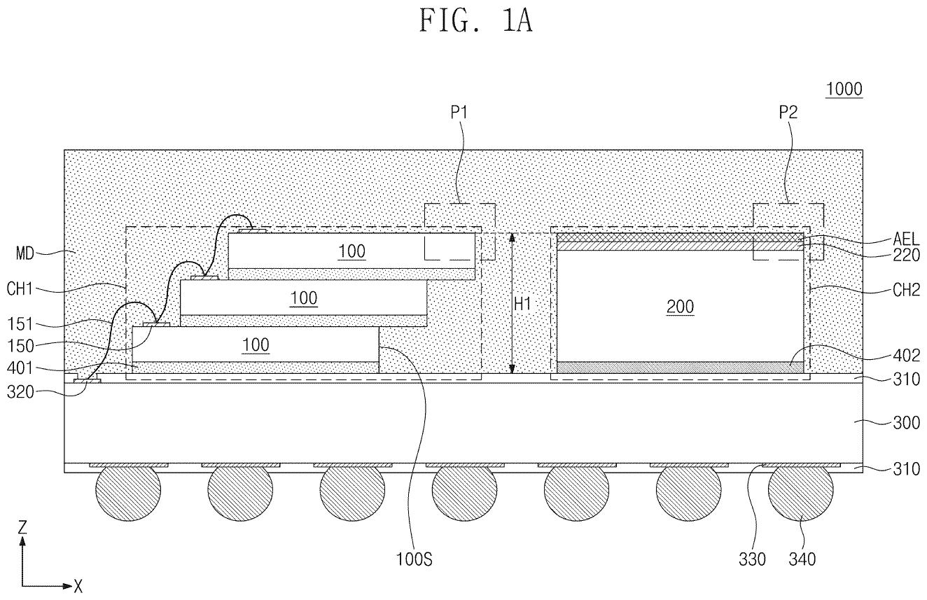

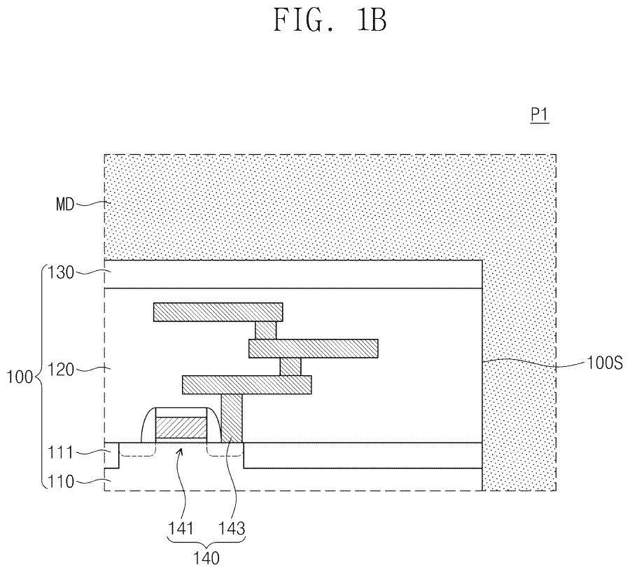

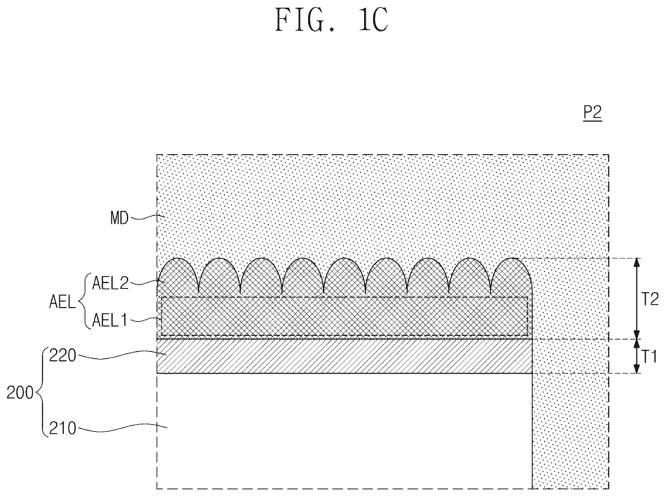

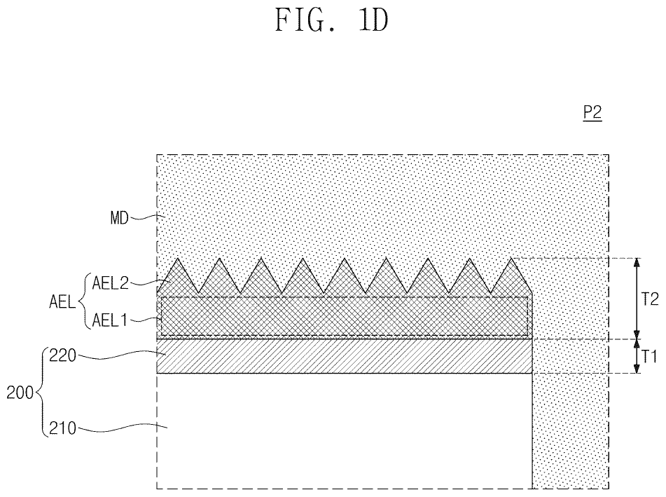

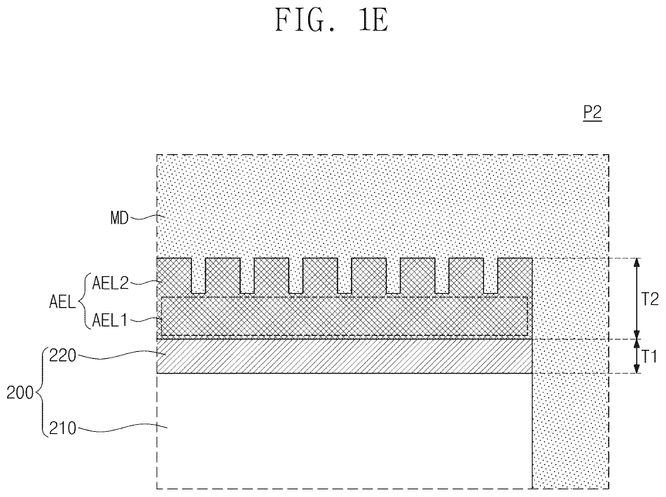

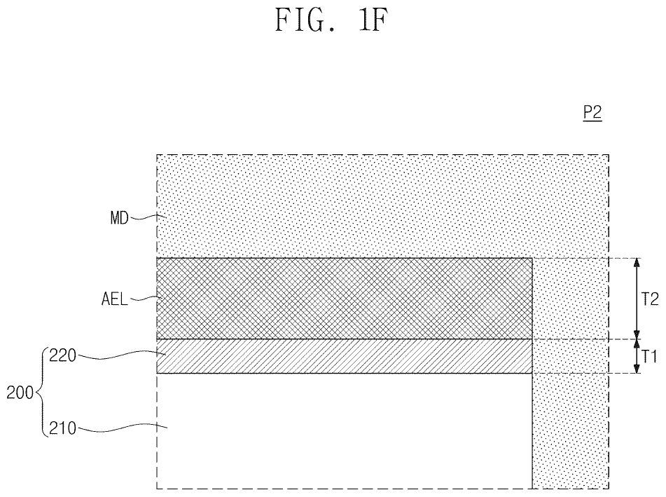

FIG. 1A is a cross-sectional view of a semiconductor package according to embodiments of the inventive concepts. FIG. 1B is an enlarged view of portion ‘P1’ of FIG. 1A. FIGS. 1C to 1F are enlarged views of portion ‘P2’ of FIG. 1A according to embodiments of the inventive concepts.

Referring to FIGS. 1A and 1B, a semiconductor package 1000 according to embodiments of the inventive concepts includes a package substrate 300, a first chip structure CH1, a second chip structure CH2, and a mold layer MD.

The package substrate 300 may be, for example, a double-sided and/or multi-layer printed circuit board. The package substrate 300 includes a body layer. Thermosetting resin such as epoxy resin, thermoplastic resin such as polyimide, and/or resin impregnated with reinforcing materials such as glass fiber and/or inorganic filler (e.g., prepreg and/or Fire resist-4 (FR4)), and/or photocurable resin may be used as the body layer, but the examples are not particularly limited thereto. The package substrate 300 may include bonding pads 320 disposed on an upper surface and lower conductive pads 330 disposed on a lower surface. External connectors 340 may be bonded to the lower conductive pads 330. The external connectors 340 may include at least one of a conductive bump, a conductive pillar, and a solder ball. The bonding pad 320 may be electrically connected to the lower conductive pads 330. For example, a redistribution pattern (not illustrated) may be included in the package substrate 300, and may form an electrical signal path between the bonding pad 320 and the lower conductive pads 330. Substrate passivation layers 310 may be provided to cover the upper surface of the package substrate 300 and the bonding pad 320, and the lower surface of the package substrate 300 and the lower conductive pads 330. The substrate passivation layers 310 may be formed of, for example, solder resists, such as a photo-solder resist (PSR).

The first chip structure CH1 may be disposed on the package substrate 300. The first chip structure CH1 may be composed of a plurality of first semiconductor dies 100. In at least some embodiments, each of the first semiconductor dies 100 may be a memory chip. The memory chip may include, for example, a volatile memory chip such as random access memory (RAM), static RAM (SRAM), or a non-volatile memory chip such as phase-change RAM PRAM, magnetoresistive RAM MRAM, resistive RAM RRAM, flash memory, and/or the like. The first semiconductor dies 100 may be semiconductor chips of the same or different structures. The first semiconductor dies 100 may each include a first semiconductor substrate 110, an interlayer insulating layer 120, and a first chip pad 150. The first chip pads 150 of the first semiconductor dies 100 may be connected to a bonding wire 151.

The first semiconductor substrate 110 may be a semiconductor single crystal substrate, a silicon on insulator (SOI) substrate, or the like. Integrated circuits 140 may be disposed on the first semiconductor substrate 110. The integrated circuits 140 may include, for example, transistors 141 and multi-layered internal wirings 143. A device isolation layer 111 may be disposed on the first semiconductor substrate 110 to define an active region for the transistors 141. An interlayer insulating layer 120 may be disposed to cover the first semiconductor substrate 110 and the integrated circuits 140. The interlayer insulating layer 120 may have a single-layer or multi-layer structure of at least one of silicon oxide, silicon nitride, silicon oxynitride, and porous insulator. A chip passivation layer 130 covering the interlayer insulating layer 120 may be disposed on the first semiconductor substrate 110. The chip passivation layer 130 may include polyimide.

In at least some embodiments, the first semiconductor dies 100 may be stacked in a step shape in the first direction X. Alternatively, although not shown, the first semiconductor dies 100 may be alternately stacked in the first direction X and an opposite direction thereof. Accordingly, one sidewall 100S of the first semiconductor dies 100 may not be vertically aligned with each other. However, the inventive concepts are not limited thereto, and the first semiconductor dies 100 may be stacked in parallel with each other such that one sidewall 100S of the first semiconductor dies 100 may be vertically aligned with each other. First adhesive layers 401 may be interposed between the first semiconductor dies 100, respectively. The first adhesive layer 401 may include die attach film (DAF) and/or epoxy resin. One of the first adhesive layers 401 may be interposed between the package substrate 300 and the first semiconductor die 100 disposed at the lowest layer in the first chip structure CH1.

First chip pads 150 may be disposed on edges of the upper surfaces of the first semiconductor dies 100, respectively. Bonding wires 151 may be provided to connect the first chip pads 150, respectively, and to connect the first chip pads 150 and the bonding pad 320. The bonding wires 151 may connect the first chip pads 150 of the first semiconductor dies 100 in a row and may be in contact with the bonding pad 320. Accordingly, the first chip structure CH1 may be electrically connected to the package substrate 300 through bonding wires 151.

The second chip structure CH2 may be disposed on the package substrate 300 and may be disposed next to the first chip structure CH1. The second chip structure CH2 may include a second semiconductor substrate 200, an oxide layer 220, and an adhesion enhancer layer AEL. The second semiconductor substrate 200 may be a semiconductor single crystal substrate, a silicon on insulator (SOI) substrate, or the like. In at least some embodiments, the second semiconductor substrate 200 may be a memory controller. In at least some embodiments, the second semiconductor substrate 200 does not include integrated circuits such as transistors and internal wiring. The second semiconductor substrate 200 does not include an interlayer insulating layer and a chip passivation layer. The second semiconductor substrate 200 may not be electrically connected to the package substrate 300. On the other hand, the oxide layer 220 may be disposed on the upper surface of the second semiconductor substrate 200. The oxide layer 220 may include SiO₂. The adhesion enhancer layer AEL in contact with the mold layer MD may be interposed on the upper surface of the oxide layer 220. The adhesion enhancer layer AEL may include an acrylic polymer.

A second adhesive layer 402 may be interposed between the lower surface of the second chip structure CH2 and the package substrate 300. The second adhesive layer 402 may include die attach film (DAF) or epoxy resin. The first chip structure CH1 and the second chip structure CH2 may have the same first height H1.

The package substrate 300, the first chip structure CH1, the second chip structure CH2, and the bonding wires 151 may be covered with a mold layer MD. The mold layer MD may include, for example, an insulating resin such as epoxy-based molding compound (EMC). The mold layer MD may further include a filler, and the filler may be dispersed in the insulating resin. The filler may include, for example, silicon oxide (SiO₂).

The chip passivation layer 130 on the first semiconductor die 100 disposed at an uppermost end of the first chip structure CH1 may be in direct contact with the mold layer MD. As a result, an interface may be formed between the polyimide polymer of the chip passivation layer 130 and the epoxy polymer constituting the mold layer MD. An adhesive force between polymer membranes may be stronger than an adhesive force between inorganic membranes and polymer membranes. Therefore, when performing a preconditioning test, which is a reliability evaluation, interlayer delamination does not easily occur at the interface between the upper surface of the first chip structure CH1 and the mold layer MD due to the adhesive force between the upper surface of the first chip structure CH1 and the mold layer MD.

In the inventive concepts, an upper surface of the oxide layer 220 in the second chip structure CH2 is covered with an adhesion enhancer layer AEL. As a result, the adhesion enhancer layer AEL is interposed between the oxide layer 220 and the mold layer MD such that the oxide layer 220 is not in direct contact with the mold layer MD, and the interface is formed between polymer of the adhesion enhancer layer AEL and polymer of the mold layer MD. Accordingly, the adhesion between the upper surface of the second chip structure CH2 and the mold layer MD may increase. Therefore, when performing a preconditioning test, the interlayer delamination that occurs at the interface between the upper surface of the second chip structure CH2 and the mold layer MD may be prevented and/or mitigated. As described above, the interlayer delamination may be prevented and/or mitigated, and the semiconductor package 1000 with improved reliability may be provided.

Referring to FIGS. 1C to 1E, for example, a surface of the adhesion enhancer layer AEL may have a concavo-convex structure. The adhesion enhancer layer AEL may include a main portion AEL1 and a plurality of protrusions AEL2 disposed on the main portion AEL1. The main portion AEL1 and the protrusions AEL2 may be integrated with each other, and the protrusions AEL2 may each have cross-sections in a shape of a triangle, square, semicircle, and/or the like. However, the inventive concepts are not limited thereto, and the protrusions AEL2 may have cross-sections of various shapes. A surface area of the adhesion enhancer layer AEL may be increased due to the non-flat cross-sectional shape of the protrusions AEL2, and a surface adhesion between the adhesion enhancer layer AEL and the mold layer MD, and interlayer delamination between the second chip structure CH2 and the mold layer MD may be prevented and/or mitigated.

Referring to FIG. 1F, according to embodiments of the inventive concepts, the surface of the adhesion enhancer layer AEL may have a flat shape. Even when the surface of the adhesion enhancer layer AEL is flat, an interface is formed between the polymer of the adhesion enhancer layer AEL and the polymer of the mold layer MD, thereby increasing the adhesion between the adhesion enhancer layer AEL and the mold layer MD.

The adhesion between the adhesion enhancer layer AEL and the mold layer MD may be greater than the adhesion between the mold layer MD and the oxide layer 220. As illustrated in FIGS. 1A to 1F, the oxide layer 220 may have a first thickness T1; the adhesion enhancer layer AEL may have a second thickness T2; and the second thickness T2 may be greater than the first thickness T1.

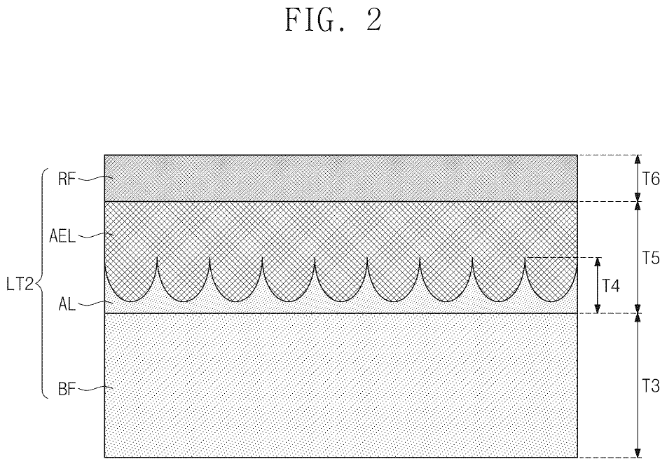

FIG. 2 is a cross-sectional view of a wafer surface protection tape according to embodiments of the inventive concepts.

Referring to FIG. 2, a second wafer surface protection tape LT2 may include a second base film BF2, a second sacrificial adhesive layer AL2 disposed on the second base film BF2, an adhesion enhancer layer AEL disposed on the second sacrificial adhesive layer AL2, and a release film RF disposed on the adhesion enhancer layer AEL.

For example, the second base film BF2 may include polyolefin and may have a third thickness T3 of 1 μm to 200 μm. The second sacrificial adhesive layer (AL2) may include at least one of polyethylene (PE), propylene oxide (PO), polyethylene terephthalate (PET), and polyamide (PA), and may have a fourth thickness T4 of 2.5 μm to 50 μm. The second base film BF2 and the second sacrificial adhesive layer AL2 may be deteriorated by ultraviolet irradiation and removed before a dicing process of the second chip structure CH2. The second base film BF2 and the second sacrificial adhesive layer AL2 may be formed of an ultraviolet non-curable material that has characteristics of being deteriorated by ultraviolet irradiation.

The adhesion enhancer layer AEL may include an acrylic polymer and may have a fifth thickness T5 of 1 μm to 100 μm. The adhesion enhancer layer AEL may be formed of an ultraviolet curable material that has characteristics of being cured by ultraviolet irradiation to be present in a final structure of the second chip structure CH2. When forming the adhesion enhancer layer AEL, 2-hydroxyethyl acrylate may be used as a monomer, poly(ethylene glycol) methyl ether acrylate containing hydroxyl groups can be used as a comonomer, and poly(ethylene glycol) diacrylate can be used as a crosslinking agent.

The adhesion enhancer layer AEL may have a main portion AEL1 and protrusions AEL2 in the same/similar manner as described with reference to FIGS. 1C to 1E. A surface of the second sacrificial adhesive layer AL2 may have a concavo-convex structure. The second sacrificial adhesive layer AL2 may fill the space between the protrusions AEL2 of the adhesion enhancer layer AEL described with reference to FIGS. 1C to 1E.

A release film RF may include polyethylene terephthalate (PET) and may have a sixth thickness T6 of 1 μm to 40 μm. The release film RF may serve to protect the surface of the second sacrificial adhesive layer AL2 or the adhesion enhancer layer AEL, and the release film RF may be peeled from the second wafer surface protection tape LT2 before attaching the semiconductor wafer to the second wafer surface protection tape LT2.

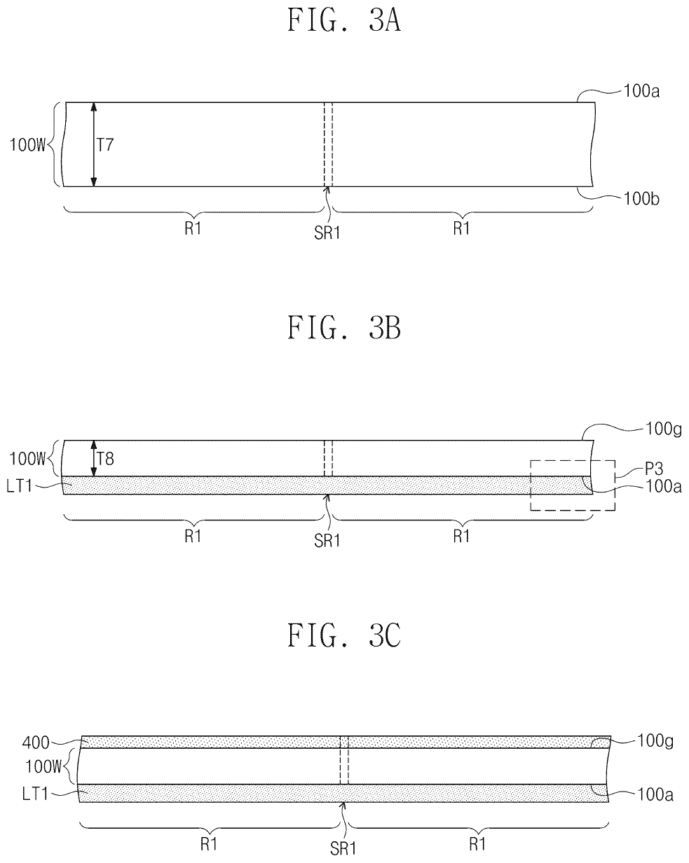

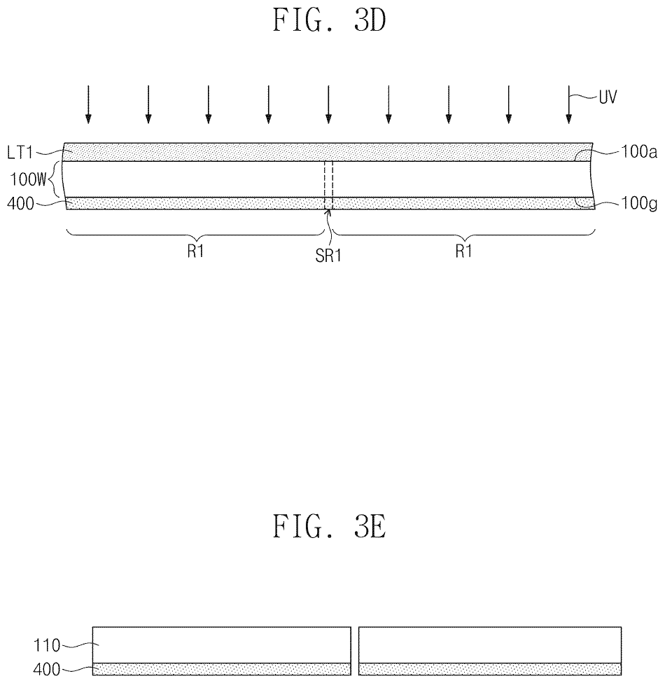

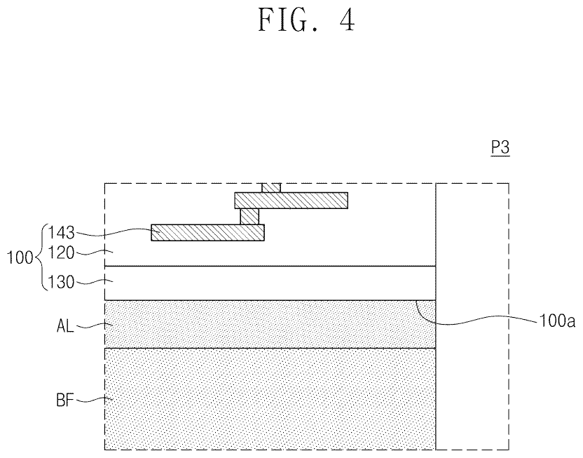

FIGS. 3A to 3E are cross-sectional views sequentially showing the process of fabricating a first semiconductor die of FIG. 1A according to embodiments of the inventive concepts. FIG. 4 is an enlarged view of portion ‘P3’ of FIG. 3B.

Referring to FIG. 3A, a first semiconductor die wafer 100W is prepared. The first semiconductor die wafer 100W may have a plurality of first chip regions R1 and a first separation region SR1 therebetween. The first chip regions R1 may have a structure of the first semiconductor die 100 described with reference to FIGS. 1A and 1B, respectively. The first separation region SR1 may be a scribe lane region. The first semiconductor die wafer 100W may include a first front surface 100a and a first back surface 100b facing each other. The first semiconductor die wafer 100W has a seventh thickness T7.

Referring to FIGS. 3B and 4, a first wafer surface protection tape LT1 is provided. The first wafer surface protection tape LT1 may include a first base film BF1 and a first sacrificial adhesive layer AL1 disposed on the first base film BF1. The first wafer surface protection tape LT1 may not include the adhesion enhancer layer AEL of FIG. 2. Although not shown, the first wafer surface protection tape LT1 may further include a release film RF on a first sacrificial adhesive layer AL1. The first semiconductor die wafer 100W may be attached to the first wafer surface protection tape LT1 such that the first front surface 100a of the first semiconductor die wafer 100W is contact with the first sacrificial adhesive layer AL1 of the first wafer surface protection tape LT1. When there is a release film RF on the first sacrificial adhesive layer AL1 in the first wafer surface protection tape LT1, the release film RF on the first sacrificial adhesive layer AL1 may be peeled off to expose the first sacrificial adhesive layer AL1 before attaching the first semiconductor die wafer 100W on the first wafer surface protection tape LT1.

After attaching the first semiconductor die wafer 100W on the first wafer surface protection tape LT1, the first back surface 100b of the first semiconductor die wafer 100W is ground with a wafer grinding device to make the first semiconductor die wafer 100W thin. The first semiconductor die wafer 100W may have a first grinding surface 100g. The ground the first semiconductor die wafer 100W may have an eighth thickness T8, and the eighth thickness T8 may be smaller than the seventh thickness T7.

Referring to FIG. 3C, the first adhesive layer 401 may be provided on the first ground surface 100g of the first semiconductor die wafer 100W. The first adhesive layer 401 may include die attach film (DAF), epoxy resin, or the like.

Referring to FIGS. 3D and 4, ultraviolet rays UV (e.g., with a wavelength of about 360 nm) may be irradiated onto the first wafer surface protection tape LT1 to remove the first wafer surface protection tape LT1 from the first front surface 100a of the first semiconductor die wafer 100W. When irradiated with the ultraviolet rays UV, a bonding force between polymer chains within the first sacrificial adhesive layer AL1 of the first wafer surface protection tape LT1 is reduced to decrease an adhesive strength of the first sacrificial adhesive layer AL1, and thus the first sacrificial adhesive layer AL1 has physical characteristics that facilitate peeling from the first front surface 100a.

Referring to FIG. 3E, a dicing process (e.g., using a laser) may be performed on the first semiconductor die wafer 100W from which the first wafer surface protection tape LT1 has been removed, to remove the first separation region SR1 and form a plurality of first semiconductor dies 100. The plurality of first semiconductor dies 100 may have the same/similar structure to the first semiconductor dies 100 of FIG. 1A.

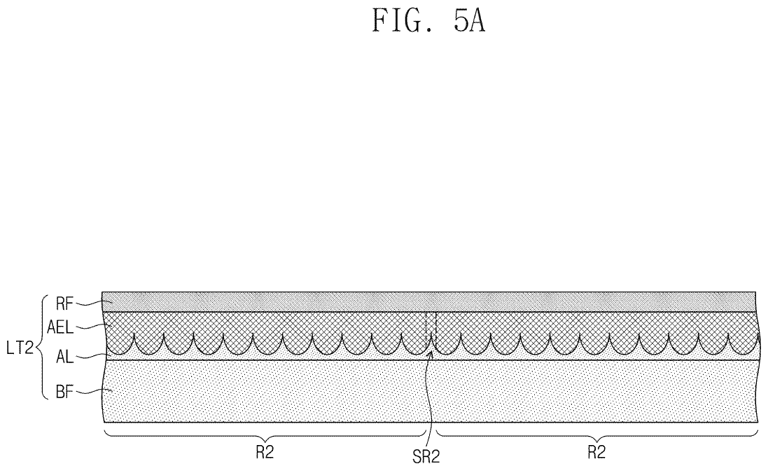

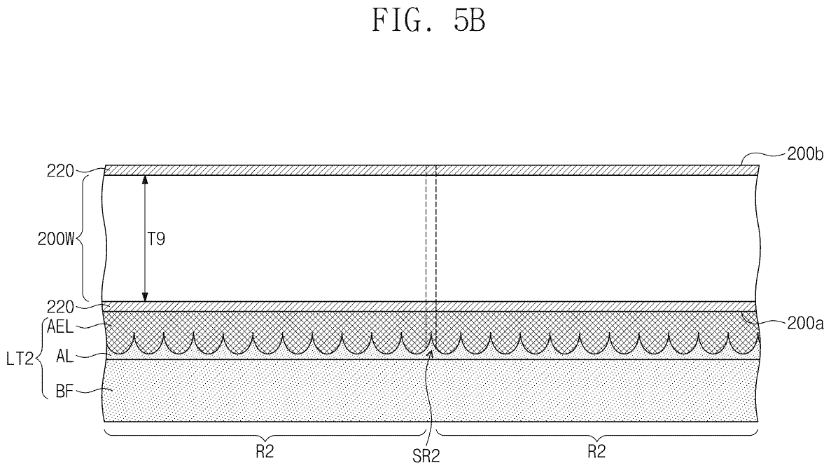

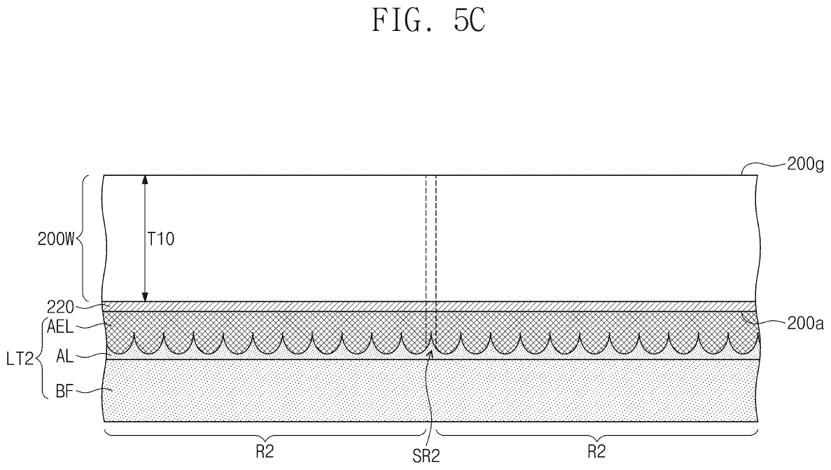

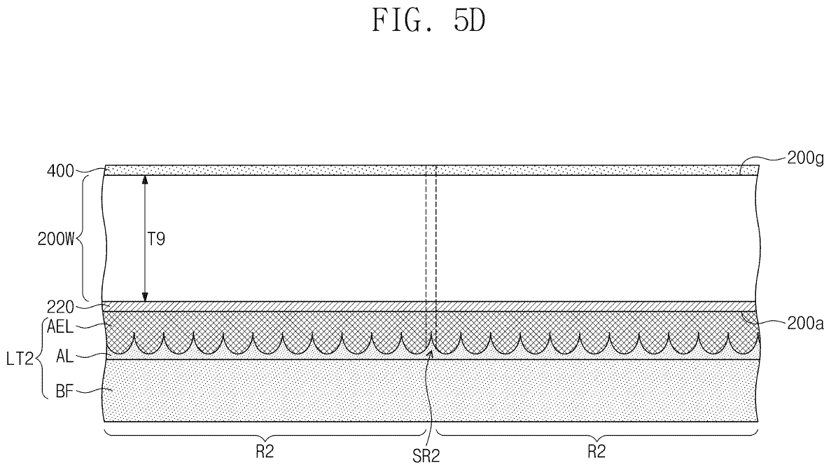

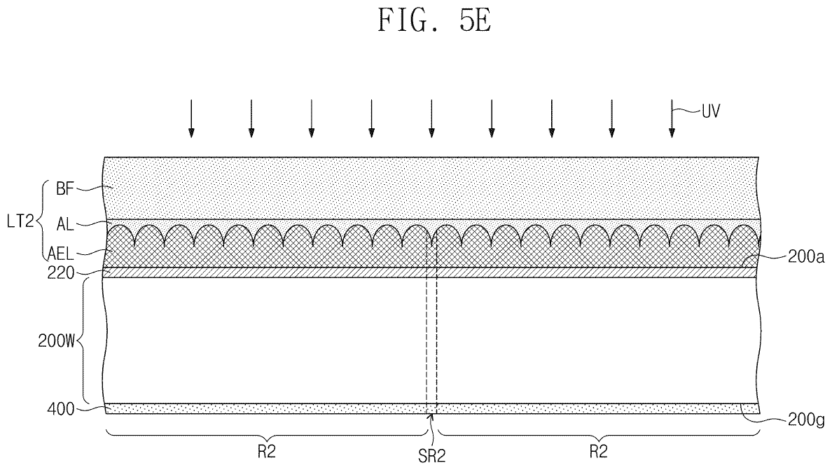

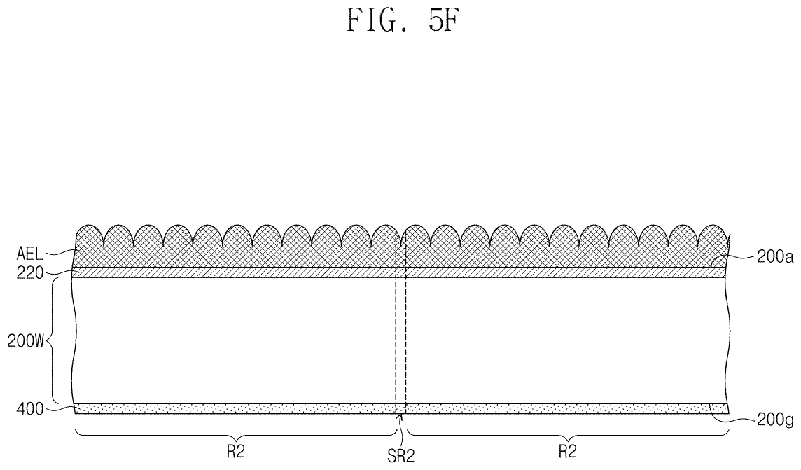

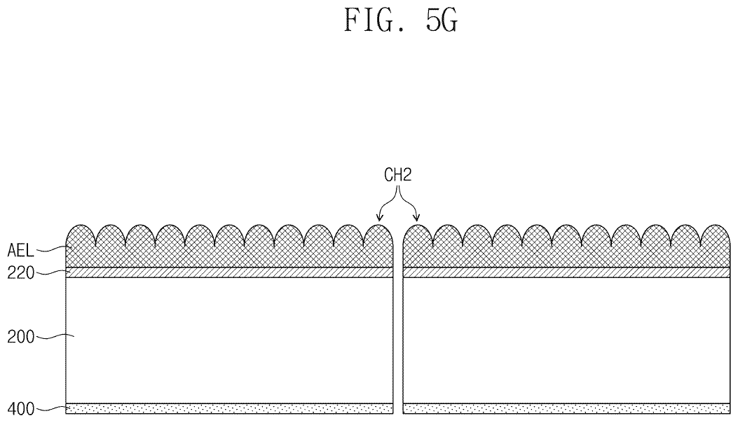

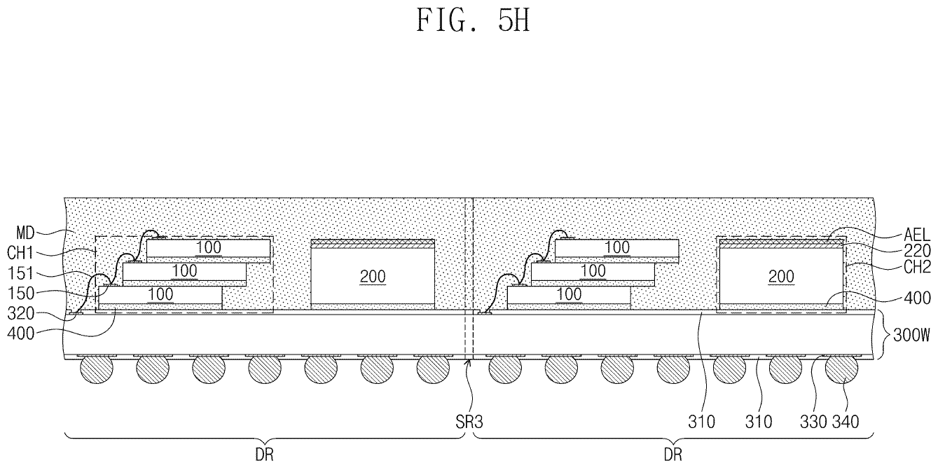

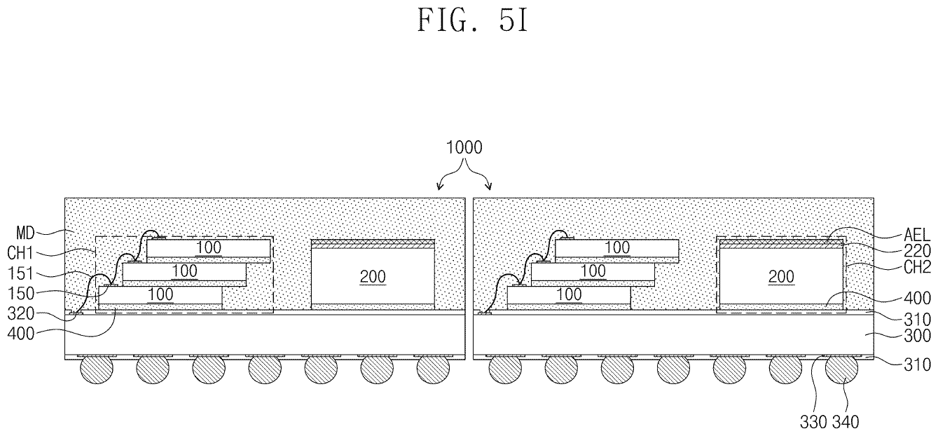

FIGS. 5A to 5I are cross-sectional views sequentially showing the process of fabricating a semiconductor package of FIG. 1A according to embodiments of the inventive concepts.

Referring to FIG. 5A, a second wafer surface protection tape LT2 may be prepared. The second wafer surface protection tape LT2 may include a second base film BF2, a second sacrificial adhesive layer AL2 disposed on the second base film BF2, an adhesion enhancer layer AEL disposed on the second sacrificial layer AL2, and a release film RF disposed on the adhesion enhancer layer AEL. The second wafer surface protection tape LT2 may be the same (and/or substantially similar) to the second wafer surface protection tape LT2 described in FIG. 2. That is, the surface of the second sacrificial adhesive layer AL2 may be formed to have a concavo-convex structure. However, the embodiments are not limited thereto. The second sacrificial adhesive layer AL2 may be manufactured through a coating and etching process. The adhesion enhancer layer AEL may be coated on the second sacrificial adhesive layer AL2 and formed. Accordingly, the adhesion enhancer layer AEL may be formed to have a main portion AEL1 and protrusions AEL2, as described with reference to FIGS. 1C to 1E.

Referring to FIG. 5B, a second semiconductor substrate wafer 200W coated with an oxide layer 220 is prepared and attached to the second wafer surface protection tape LT2. The second semiconductor substrate wafer 200W may have a plurality of second chip regions R2 and a second separation region SR2 therebetween. The second chip regions R2 may have a structure of the second chip structure CH2 described with reference to FIGS. 1A and 1C to 1E, respectively. The second separation region SR2 may be a scribe lane region. The second semiconductor substrate wafer 200W may include a second front surface 200a and a second back surface 200b facing each other. The second semiconductor substrate wafer 200W has a ninth thickness T9.

In at least some embodiments, the release film RF is peeled from the second wafer surface protection tape LT2 to expose the adhesion enhancer layer AEL before attaching the second semiconductor substrate wafer 200W on the second wafer surface protection tape LT2. Thereafter, the second semiconductor substrate wafer 200W is attached to the second wafer surface protection tape LT2 such that the second front surface 200a is in contact with the adhesion enhancer layer AEL.

Referring to FIG. 5C, the second back surface 200b of the second semiconductor substrate wafer 200W is wafer ground after attaching the second semiconductor substrate wafer 200W on the second wafer surface protection tape LT2. A thickness of the second semiconductor substrate wafer 200W is made thin, e.g., using grinding with a device. For example, in at least some embodiments, a chemical-mechanical polishing (CMP) apparatus may be used. The second semiconductor substrate wafer 200W may have a second grinding surface 200g. The ground second semiconductor substrate wafer 200W may have a tenth thickness T10, and the tenth thickness T10 may be smaller than the ninth thickness T9.

Referring to FIG. 5D, a second adhesive layer 402 may be provided on the second grinding surface 200g of the second semiconductor substrate wafer 200W. The second adhesive layer 402 may include die attach film (DAF), epoxy resin, and/or the like.

Referring to FIGS. 5E and 5F, ultraviolet rays UV with a wavelength of 360 nm are irradiated on the second wafer surface protection tape LT2 to remove a second base film BF2 and the second sacrificial adhesive layer AL2 of the second wafer surface protection tape LT2 from the second semiconductor substrate wafer 200W. When irradiated with the ultraviolet rays UV, a bonding strength between the polymer chains of the base film BF and the second sacrificial adhesive layer AL2 decreases, and the adhesion of the second sacrificial adhesive layer AL2 decrease, and thus the second sacrificial adhesive layer AL2 has physical characteristics that facilitate peeling from the second front surface 200a. Meanwhile, when irradiated with the ultraviolet rays UV, the adhesion enhancer layer AEL is hardened and fixed on the second front surface 200a. A surface of the adhesion enhancer layer AEL may have a concavo-convex structure, and/or the adhesion enhancer layer AEL may have the same/similar structure as the adhesion enhancer layer AEL described in FIGS. 1C to 1E.

Referring to FIG. 5G, a dicing process (e.g., using a laser) may be performed on the second semiconductor substrate wafer 200W from which the second base film BF2 and the second sacrificial adhesive layer AL2 have been removed, and thus the second separation region SR2 may be removed and a plurality of second chip structures CH2 may be formed. The plurality of second chip structures CH2 may have the same and/or substantially similar structure to the second chip structure CH2 described in FIG. 1A.

Referring to FIG. 5H, a board-sized package substrate 300W is prepared. The board-sized package substrate 300W may have a plurality of device regions DR and a third separation region SR3 therebetween. Each of the device regions DR may have a structure of the semiconductor package 1000 described with reference to FIG. 1A.

The board-sized package substrate 300W may include bonding pads 320 on an upper surface, lower conductive pads 330 on a lower surface, and external connectors 340 bonded to the lower conductive pads 330. The bonding pads 320 and the lower conductive pads 330 may each be covered with a substrate passivation layer 310.

A plurality of first chip structures CH1 and a plurality of second chip structures CH2 are arranged side by side on the board-sized package substrate 300W. As the adhesion enhancer layer AEL of the second chip structures CH2 is cured and the surface is dry, the second chip structures CH2 may be attached to the board-sized package substrate 300W by performing a pickup process. The first chip structures CH1 may be formed by sequentially stacking the first semiconductor dies 100 described in FIGS. 3A to 3E. The first semiconductor dies 100 are connected to each other through bonding wires 151, and the first chip structures CH1 are electrically connected to the board-sized package substrate 300W through bonding wires 151. The second chip structures CH2 may have a structure of the second chip structures CH2 described in FIGS. 5A to 5G. A mold layer MD may be formed covering the board-sized package substrate 300W, the first chip structures CH1, and the second chip structures CH2.

Referring to FIG. 5I, a dicing process (e.g., using a laser) may be performed to remove the third separation region SR3 to form a plurality of semiconductor packages 1000. As described above, the semiconductor packages 1000 of FIG. 1A may be formed. Due to an adhesive force between the adhesion enhancer layer AEL and the mold layer MD disposed on the second chip structure CH2, interlayer delamination which may occur at the interface between the second chip structure CH2 and the mold layer MD may be prevented or mitigated, thereby decreasing process defects, reducing defect rate, and improving yield.

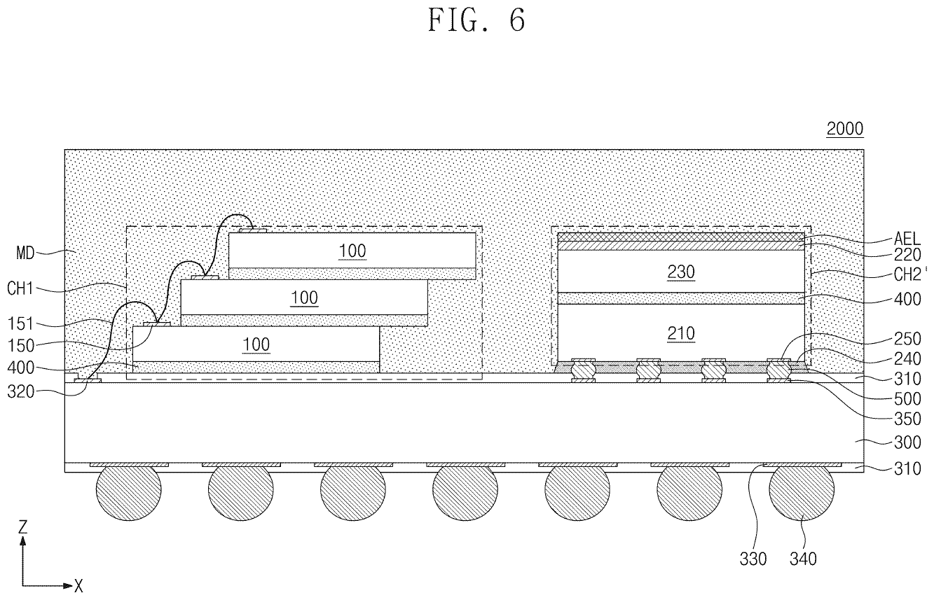

FIG. 6 is a cross-sectional view of a semiconductor package according to embodiments of the inventive concepts.

Referring to FIG. 6, a semiconductor package 2000 according to embodiments of the inventive concepts may include a package substrate 300, a first chip structure CH1, a second chip structure CH2′, and a mold layer MD.

The package substrate 300 may be, for example, a double-sided or multi-layer printed circuit board. The package substrate 300 may include a bonding pad 320 and upper conductive pads 350 disposed on an upper surface, and lower conductive pads 330 disposed on a lower surface. External connectors 340 may be bonded to the lower conductive pads 330. The external connectors 340 may include at least one of a conductive bump, a conductive pillar, and a solder ball. The bonding pad 320 and the upper conductive pads 350 may be electrically connected to the lower conductive pads 330. Substrate passivation layers 310 may be provided covering an upper surface of the package substrate 300, the bonding pad 320 and the upper conductive pads 350, and the lower surface of the package substrate 300 and the lower conductive pads 330. The substrate passivation layers 310 may be formed of, for example, photo-solder resist (PSR).

The first chip structure CH1 may be disposed on the package substrate 300. The first chip structure CH1 may be composed of a plurality of first semiconductor dies 100. Each of the first semiconductor dies 100 may be a memory chip. The first semiconductor dies 100 may be semiconductor chips of the same or different structures. The first semiconductor dies 100 may each include a first semiconductor substrate (not shown), integrated circuits (not shown), and a first chip pad 150. The first chip pads 150 of the first semiconductor dies 100 may be connected to a bonding wire 151. The first semiconductor substrate (not shown) may be a semiconductor single crystal substrate, a silicon on insulator (SOI) substrate, or the like.

The first chip pads 150 may be disposed on the edges of the upper surfaces of the first semiconductor dies 100, respectively. Bonding wires 151 may be provided to connect the first chip pads 150, respectively, and to connect the first chip pads 150 and the bonding pad 320. The bonding wires 151 may connect the first chip pads 150 of the first semiconductor dies 100 in a row and may be in contact with the bonding pad 320. Accordingly, the first chip structure CH1 may be electrically connected to the package substrate 300 through the bonding wires 151.

The second chip structure CH2′ may be disposed on the package substrate 300 and may be disposed next to the first chip structure CH1. The second chip structure CH2′ may include a second semiconductor die 210 and a reinforcing material 230. The second semiconductor die 210 may include a second semiconductor substrate (not shown), second chip pads 250, and integrated circuits (not shown). The reinforcing material 230 does not include integrated circuits. The reinforcing material 230 may include a material such as silicon (Si), for example.

The second semiconductor die 210 may be connected to the package substrate 300 using a flip chip bonding manner through internal connectors 500. The internal connectors 500 may connect the corresponding second chip pads 250 to the upper conductive pads 350. For example, the internal connectors 500 may include solder bumps or solder balls. The internal connectors 500 may include, for example, at least one of copper, aluminum, nickel, lead, and tin. An underfill 240 that fills the second semiconductor die 210 and the package substrate 300 and protects the internal connectors 500 may be provided. The underfill 240 may include epoxy resin.

First adhesive layers 401 may be interposed between the first semiconductor dies 100, respectively. Additionally, a second adhesive layer 402 may be interposed between the reinforcing material 230 and the second semiconductor die 210. The first and second adhesive layers 401 and 402 may include die attach film (DAF) or epoxy resin. One of the first adhesive layers 401 may be interposed between the package substrate 300 and the first semiconductor die 100 located at the lowest layer in the first chip structure CH1. The first chip structure CH1 and the second chip structure CH2′ may have the same second height H2.

The package substrate 300, the first chip structure CH1, the second chip structure CH2′, and the bonding wires 151 may be covered with a mold layer MD. The mold layer MD may include, for example, an insulating resin such as epoxy-based molding compound (EMC). The mold layer MD may further include a filler, and the filler may be dispersed in the insulating resin. The filler may include, for example, silicon oxide (SiO₂).

A chip passivation layer (not shown) may be disposed on the first semiconductor dies 100. The chip passivation layer (not shown) may include polyimide. An upper surface of the first semiconductor die 100 disposed at an upper surface of the first chip structure CH1 may be in direct contact with the mold layer MD. As a result, an interface may be formed between the polyimide polymer of the chip passivation layer (not shown) and the epoxy polymer constituting the mold layer (MD). Therefore, when performing a preconditioning test, which is a reliability evaluation, between the upper surface of the first chip structure CH1 and the mold layer MD, delamination between layers does not easily occur at the interface due to an adhesive force between the upper surface of the first chip structure CH1 and the mold layer MD.

An oxide layer 220 may be disposed on an upper surface of the reinforcing material 230. The oxide layer 220 may include SiO₂. In the inventive concepts, an upper surface of the oxide layer 220 in the second chip structure CH2′ may be covered with an adhesion enhancer layer AEL. The adhesion enhancer layer AEL may be the same and/or substantially similar to the adhesion enhancer layer AEL described in FIG. 2. The adhesion enhancer layer AEL may include an acrylic polymer. As a result, the adhesion enhancer layer AEL is interposed between the oxide layer 220 and the mold layer MD, and thus upper surface of the oxide layer 220 is not direct contact with the mold layer MD and an interface is formed between polymer of the adhesion enhancer layer AEL and polymer of the mold layer MD. As a result, the adhesion between an upper surface of the second chip structure CH2′ and the mold layer MD may be increased. Therefore, when performing a preconditioning test, interlayer delamination that occurs at the interface between the upper surface of the second chip structure CH2′ and the mold layer MD may be prevented and/or mitigated. As described above, interlayer delamination may be prevented and/or mitigated, and a semiconductor package 2000 with improved reliability may be implemented.

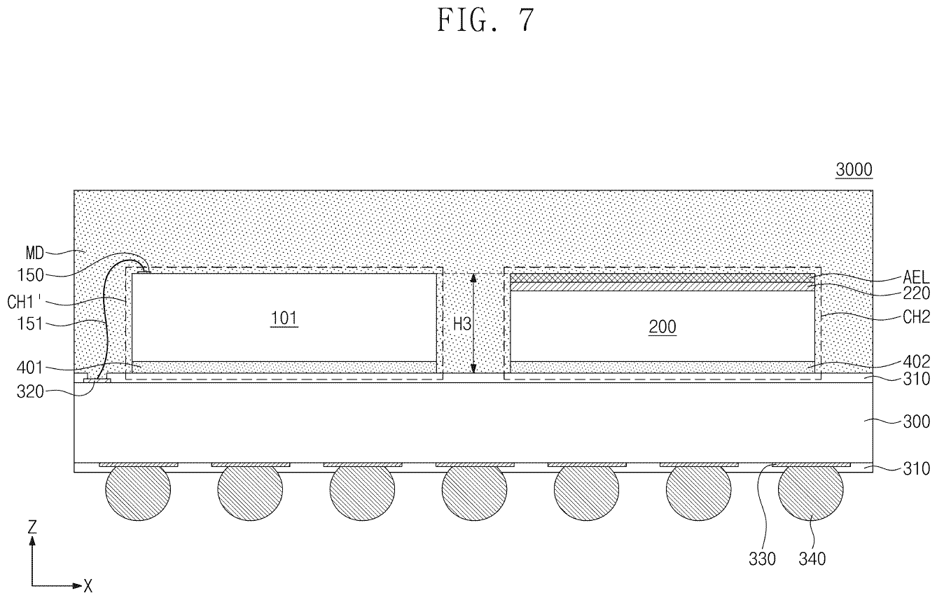

FIG. 7 is a cross-sectional view of a semiconductor package according to embodiments of the inventive concepts.

Referring to FIG. 7, a semiconductor package 3000 according to embodiments of the inventive concepts may include a package substrate 300, a first chip structure CH1′, a second chip structure CH2, and a mold layer MD. In the structure of FIG. 1A, the semiconductor package 3000 may have a single-layer structure of the first chip structure CH1′ rather than a multi-layer stacked structure. The first chip structure CH1′ may include one first semiconductor die 101. The first semiconductor die 101 may include a first semiconductor substrate (not shown) and integrated circuits (not shown), and other configurations of the first semiconductor die 101 may be the same/similar to those described with reference to FIG. 1A. The first chip structure CH1′ and the second chip structure CH2 may have the same third height H3. Other configurations of the semiconductor package 3000 may be the same/similar to those described with reference to FIG. 1A.

In the semiconductor package according to the inventive concepts, the adhesion enhancer layer containing the polymer material may be provided on the surface of the semiconductor chip, thereby increasing the interfacial adhesion between the semiconductor chip and the mold layer. As a result, the physical damage such as the delamination between the layers within the semiconductor package, thereby providing the semiconductor package with the improved durability and reliability. Additionally, the process defects such as the delamination may be resolved and the defect rate may be reduced, thereby improving the yield.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims.

1. A semiconductor package comprising:
a package substrate including external connectors on a lower surface of the package substrate;
a first chip structure on the package substrate and connected to the package substrate with a bonding wire;
a second chip structure on the package substrate and next to the first chip structure;
a mold layer covering the package substrate, the first chip structure, and the second chip structure; and
an adhesion enhancer layer on an upper surface of the second chip structure, such that the adhesion enhancer layer is in contact with the mold layer.

2. The semiconductor package of claim 1, further comprising:
an adhesive layer between an upper surface of the package substrate and at least one of a lower surface of the first chip structure or a lower surface of the second chip structure.

3. The semiconductor package of claim 1, wherein the first chip structure is composed of a plurality of sequentially stacked semiconductor dies.

4. The semiconductor package of claim 1, wherein the second chip structure further includes:
a second semiconductor substrate below the adhesion enhancer layer; and
an oxide layer between the second semiconductor substrate and the adhesion enhancer layer.

5. The semiconductor package of claim 1, wherein the adhesion enhancer layer includes a main portion and a plurality of protrusions disposed on the main portion,
the main portion and the protrusions are formed as one piece, and
wherein each of the protrusions has a triangular, square, or semicircular cross section.

6. The semiconductor package of claim 1, wherein a surface of the adhesion enhancer layer has a concavo-convex structure.

7. The semiconductor package of claim 1, wherein an upper surface of the first chip structure is in direct contact with the mold layer.

8. The semiconductor package of claim 1, wherein the first chip structure and the second chip structure have the same height.

9. A semiconductor package comprising:
a package substrate including bonding pads on an upper surface of the package substate and external connectors on a lower surface of the package substrate;
a first chip structure on the package substrate and connected to the package substrate with a bonding wire;
a second chip structure on the package substrate and next to the first chip structure; and
a mold layer covering the package substrate, the first chip structure, and the second chip structure,
wherein the first chip structure includes a plurality of semiconductor dies that are sequentially stacked,
wherein the second chip structure includes
a second semiconductor substrate,
an oxide layer on the second semiconductor substrate, and
an adhesion enhancer layer on the oxide layer and in contact with the mold layer,
wherein heights of the first chip structure and the second chip structure are same, and
wherein the adhesion enhancer layer has a thickness within a range of 1 μm to 100 μm.

10. The semiconductor package of claim 9, wherein an upper surface of the first chip structure is in direct contact with the mold layer.

11. The semiconductor package of claim 9, wherein at least some sidewalls of the plurality of semiconductor dies are not vertically aligned.

12. The semiconductor package of claim 9, further comprising:
an adhesive layer between a lower surface of the second chip structure and the package substrate.

13. The semiconductor package of claim 9, wherein
each of the plurality of semiconductor dies includes a first semiconductor substrate, integrated circuits on the first semiconductor substrate, and an interlayer insulating layer covering the integrated circuits, and
the plurality of semiconductor dies are electrically connected to the package substrate.

14. The semiconductor package of claim 13, wherein the second chip structure does not include an integrated circuit.

15. The semiconductor package of claim 13, wherein
the first chip structure further includes a chip passivation layer on the interlayer insulating layer, and
the second chip structure does not include a chip passivation layer.

16. The semiconductor package of claim 9, wherein
the adhesion enhancer layer includes a main portion and a plurality of protrusions on the main portion,
the main portion and the protrusions are formed as one piece, and
each of the protrusions has a triangular, square, or semicircular cross section.

17. The semiconductor package of claim 9, wherein the adhesion enhancer layer includes an acrylic polymer.

18. The semiconductor package of claim 9, wherein an adhesive force between the adhesion enhancer layer and the mold layer is greater than an adhesive force between the oxide layer and the mold layer.

19. The semiconductor package of claim 9, wherein
the oxide layer has a first thickness,
the adhesion enhancer layer has a second thickness, and
the second thickness is greater than the first thickness.

20. A semiconductor package comprising:
a package substrate including bonding pads on an upper surface of the package substrate and external connectors on a lower surface of the package substrate;
a first chip structure on the package substrate and connected to the package substrate with a bonding wire;
a second chip structure disposed on the package substrate and next to the first chip structure;
internal connectors between the package substrate and the second chip structure; and
a mold layer covering the substrate, the first chip structure, and the second chip structure,
wherein heights of the first chip structure and the second chip structure are same,
wherein the first chip structure includes a plurality of first semiconductor dies that are sequentially stacked,
wherein the second chip structure includes
a second semiconductor die,
an adhesive layer on the second semiconductor die,
a reinforcing material on the adhesive layer,
an oxide layer on the reinforcing material, and
an adhesion enhancer layer on the oxide layer, and
wherein the adhesion enhancer layer includes an acrylic polymer.

21.-24. (canceled)
